(19) United States
(12) Patent Application Publication
(10) Pub. No.: US 2008/0285226 A1
(43) Pub. Date: Nov. 20, 2008

(54) Electronic device

(75) Inventor: Takashi Iijima, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/219,629

(22) Filed: Jul. 24, 2008

Related U.S. Application Data
(63) Continuation of application No. PCT/JP2006/001192, filed on Jan. 26, 2006.

(51) Int. Cl. H05K 7/00

(52) U.S. Cl. 361/685; 361/687; 361/686

(57) ABSTRACT

The present invention relates to an electronic device represented by, for example, a personal computer and aims to dispose an IC card in a suitable position. The electronic device includes: a main unit 20 in the shape of a small board equipped with a keyboard 21 disposed at a rearward position on the upper surface; a heat-producing part incorporated within the main unit 20 so as to make the amount of heat produced in the back half of the main unit 20 become larger than the amount of heat produced in the front half; and a card slot formed in the front end face of the main unit 20, into which a removable IC card can be inserted.

### CROSS REFERENCE TO RELATED APPLICATIONS

This is a continuing application, filed under 35 U.S.C. §111(a), of International Application PCT/JP2006/301192, filed Jan. 26, 2006, the contents of which are incorporated herein by reference.

### TECHNICAL FIELD

The present invention relates to an electronic device represented by, for example, a personal computer.

### BACKGROUND ART

In recent years, a personal computer (hereinafter, it is abbreviated to PC) has become widespread not only in offices but also in households. As one example of this PC, a so-called notebook personal computer (hereinafter, it is abbreviated to notebook PC) has been known, which includes a main unit equipped with a keyboard on its upper surface and a display unit equipped with a display screen which can be opened and closed freely for the main unit, and when the notebook PC is used, the display unit is opened to stand against the main unit, and when the notebook PC is not used, the display screen is folded so as to overlay the keyboard.

Also recently, a so-called tablet personal computer (hereinafter, it is abbreviated to tablet PC) has emerged, which is formed of one unit having the shape of board equipped with a display screen on its upper surface, and into which instruction is input either by bringing a pen near the display screen or by touching the screen with the pen and then by recognizing the approached or touched position.

More recently, an electronic device has emerged which can be used as a notebook PC by standing its display unit, whose main unit and display unit are connected together via a biaxial connecting section that supports the units so as to open and close freely and rotate freely, and which can also be used as a tablet PC by overlaying the display unit on the main unit in a manner that the display screen points upward.

Miniaturization is also required for electronic devices in general such as PCs, and especially for the notebook PC and the tablet PC, the miniaturization and the slimming down is strongly requested because they are required to be highly portable. In recent years, the notebook PC or the like comes to incorporate advanced functionality that is not inferior to so-called desktop PCs and continues to incorporate higher functionality. Therefore, there is demand for realizing the miniaturization and the slimming down as well as maintaining high operability without falling behind the trend of incorporating such advanced functionality.

Here, recently, even in notebook PCs or the like, there are some types that have built-in TV receiving function, and more recently, some types begin to have built-in TV receiving function ready for digital broadcasting. Note here that digital broadcasting broadcasts video with encryption and an IC card for decoding the encryption is enclosed in any official receiver, and TV broadcasting can be enjoyed by inserting the IC card into the receiver to decode the encryption. Because of this, also in the notebook PC or the like, some types that contain digital TV broadcasting receiving function have a structure of inserting the IC card (See Documents 1 through 4 listed below).

Document 1: Japanese Patent Application Publication No. 2004-109396,

Document 2: Japanese Patent Application Publication No. 2004-274590

Document 3: Japanese Patent Application Publication No. 2005-167993

Document 4: Japanese Patent Application Publication No. 2005-198044.

Here, IC card or the like is relatively heat-sensitive, and need to be kept under not more than 50-degrees, for example. However, a large-scale LSI such as a CPU or the like is mounted on the notebook PC or the like and its inside produces high heat so that if an IC card is placed accidentally thereat, it ends up reaching over 50-degrees easily. In addition, it is desirable to place the IC card in a place that allows the IC card to be inserted and extracted as easily as possible.

In view of the above circumstances, it is an object of the present invention to provide an electronic device in which an IC card is placed in a suitable position.

### DISCLOSURE OF THE INVENTION

An electronic device according to the present invention achieving the above object includes:

an enclosure in the shape of a small board;

a heat-producing part incorporated within the enclosure so as to make the amount of heat produced in the back half of the enclosure become larger than the amount of heat produced in the front half; and

a card slot which is formed in the front end face of the enclosure and into which a removable IC card is inserted.

In the electronic device according to the present invention, a part that produces a large amount of heat is placed in the back half of the enclosure, and a card slot for an IC card is placed in the front end face of the enclosure. Accordingly, the IC card can be readily inserted and extracted and the effect of temperature can be reduced.

Here, it is desirable that the electronic device according to the present invention further includes: a card drive disposed in a position closer to the front of the enclosure to access the IC card inserted into the card slot; a hard disk unit disposed next to the card drive; and a CPU as a heat-producing part disposed deeper than the card drive and the hard disk unit.

The hard disk unit should also avoid a high temperature environment and therefore it is desirable to place the hard disk unit next to the card drive.

Moreover, in this electronic device, the enclosure may have a keyboard disposed in a rearward position on an upper surface of the enclosure, and the electronic device may further include a second enclosure in the shape of a small board on which a display screen is disposed, the second enclosure being openable and closable with respect to the former enclosure.

The present invention can be suitably applied to a notebook PC.

As described above, according to the present invention, the IC card can be placed in a suitable position that is convenient for the insertion and extraction and less affected by temperature.

### BRIEF DESCRIPTION OF THE DRAWINGS

FIG. 1 is an external perspective view of a notebook PC according to one embodiment of the present invention, when viewed diagonally from its front.

FIG. 2 is an external perspective view of the notebook PC according to one embodiment of the present invention, when viewed from a different direction than that of FIG. 1.

FIG. 3 is a diagram showing the undersurface of the main unit.

FIG. 4 is an enlarged diagram of the card slot portion at the front end of the main unit.

FIG. 5 is an enlarged diagram showing a state when the slot cover is open.

FIG. 6 is an enlarged diagram showing a state when the IC card is inserted into the card slot.

FIG. 7 is a diagram showing the inside of the main unit by placing the undersurface of the main unit pointing upward and by removing the lower cover.

FIG. 8 is an enlarged diagram of one portion in FIG. 7.

### BEST MODE FOR CARRYING OUT THE INVENTION

An embodiment of the present invention will be described below.

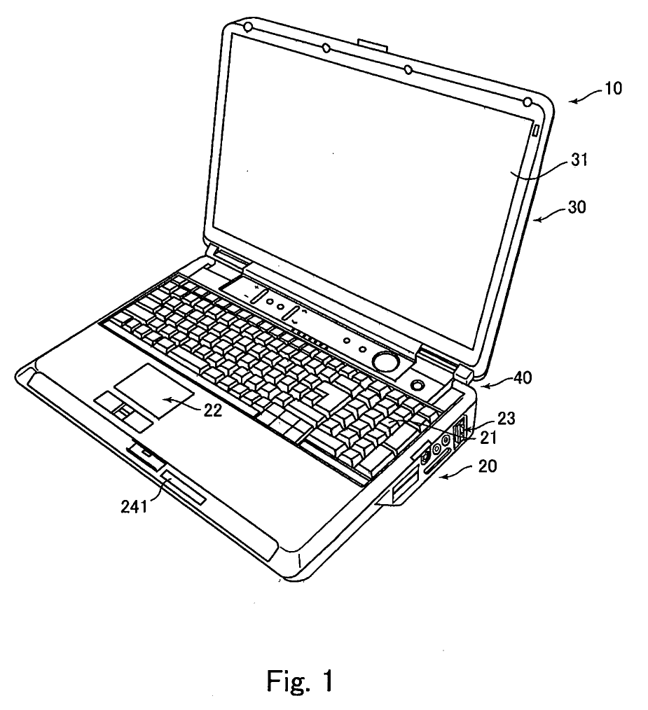

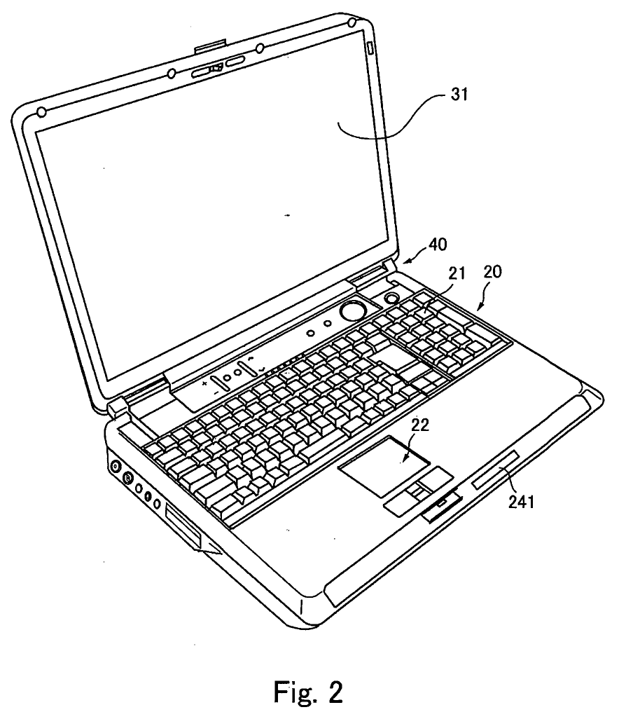

FIGS. 1 and 2 are external perspective views of the notebook PC according to one embodiment of the present invention, when viewed diagonally from its front, each from different direction.

This notebook PC 10 includes two enclosures, a main unit 20 and a display unit 30. The display unit 30 is supported by a hinge section 40 so as to open and close freely with respect to the main unit 20.

The main unit 20 is equipped with a keyboard 21 and a track pad 22 or the like on its upper surface, and to the right side, a USB connector 23, which is an element to be described later in detail, is disposed with its mating surface pointing outward.

Moreover, this notebook PC 10 incorporates built-in TV receiving function, and at the front end of the main unit 20, a slot cover 241 is disposed which covers an opening of a card slot through which IC card can be inserted and extracted freely. Here, the IC card in which key data for decoding encryption has been recorded, which is attached to a device (TV and tuner) for receiving digital broadcasting.

Furthermore, the display unit 30 has a large display screen 31 on its front.

Moreover, the hinge section 40 has a structure of supporting the display unit 30 on the main unit 20 in a manner that the display unit 30 can open and close freely with respect to the main unit 20.

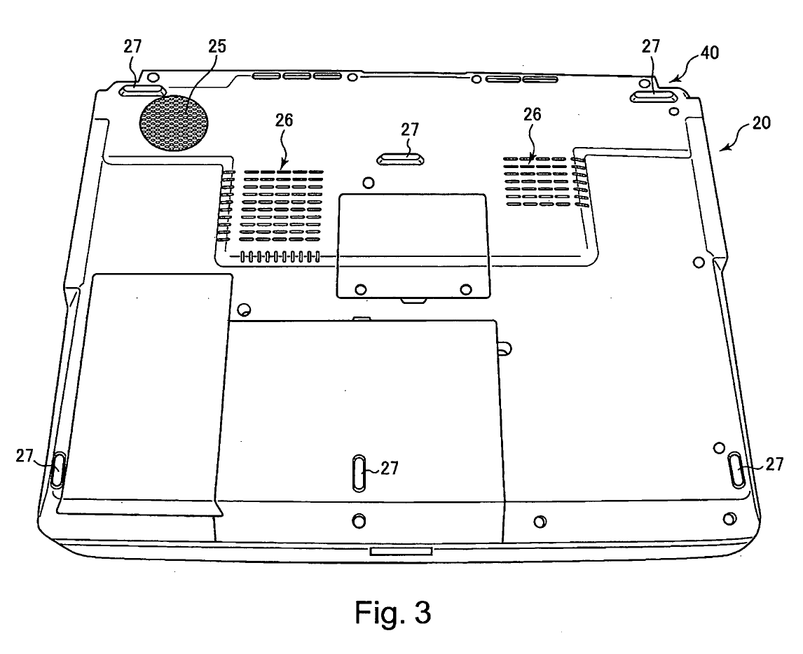

FIG. 3 is a diagram showing the undersurface of the main unit 20.

In a position near the hinge section 40 on the undersurface of this main unit 20, a woofer 25 can be seen. Also, in a position that is closer to the hinge section 40 side than the center of the main unit 20, air holes 26 for circulating air within the main unit are formed. This is because heat-producing parts such as a CPU and the like are disposed in the back of the main unit 20 in order to make the amount of heat produced in the back half of the main unit 20 become larger than the amount of heat produced in the front half thereof. Moreover, on the undersurface of this main unit 20, floor-standing pads 27 are provided in a manner that they protrude a little from the undersurface of the main unit 20 to prevent, when the main unit 20 is placed on the desk or the like, the woofer 25 and the air holes 26 from touching the surface of the desk.

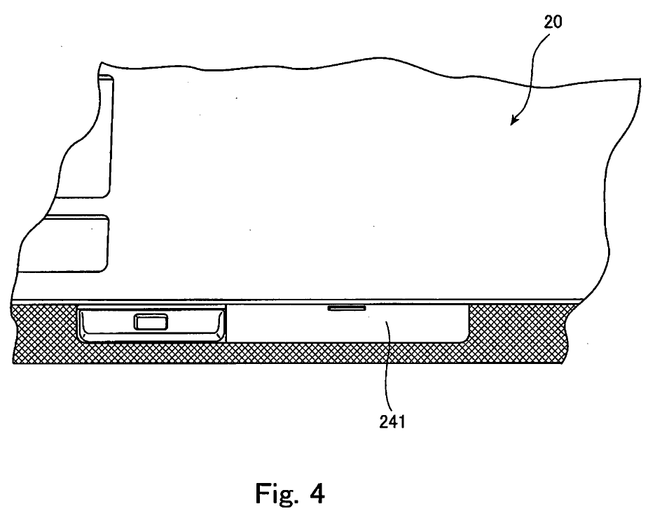

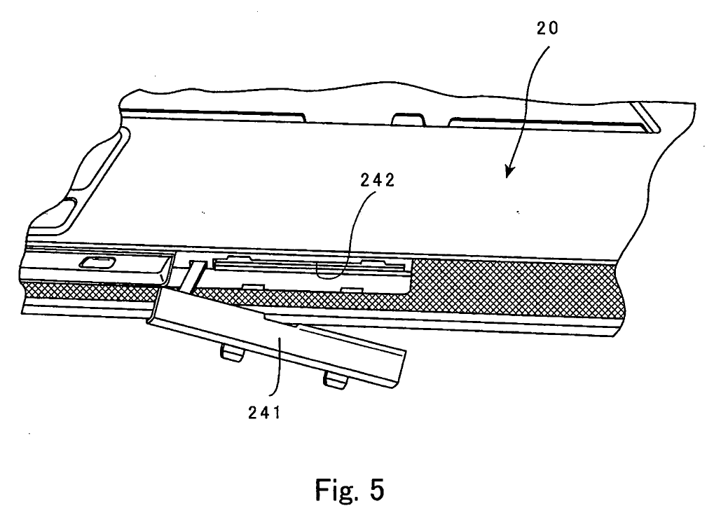

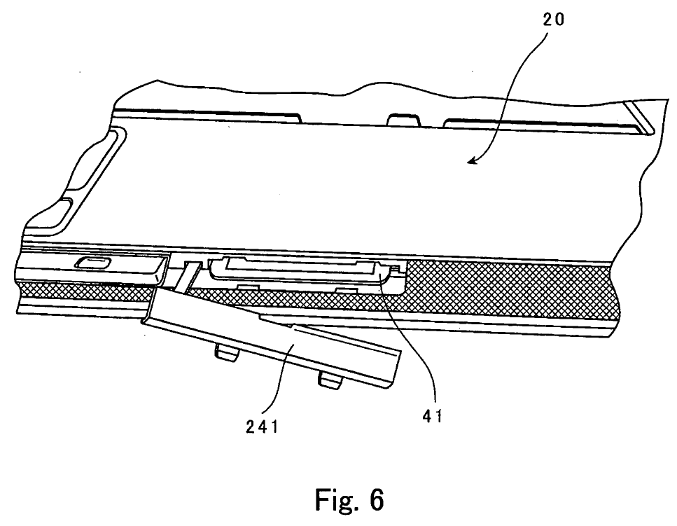

FIG. 4 is an enlarged diagram of the card slot portion in the front end of the main unit 20 (a state when the slot cover is closed). FIG. 5 is an enlarged diagram of a state when the slot cover is open in the same portion as in FIG. 4. FIG. 6 is an enlarged diagram of a state when the IC card has been inserted into the card slot.

As shown in FIG. 4, at the front end of the main unit 20, the slot cover 241 for covering the card slot is provided and when the slot cover 241 is opened, a card slot 242 for inserting the IC card appears as shown in FIG. 5.

As shown in FIG. 6, after an IC card 41 is inserted into the card slot 242, the slot cover 241 returns to its original position with the IC card 41 inserted therein.

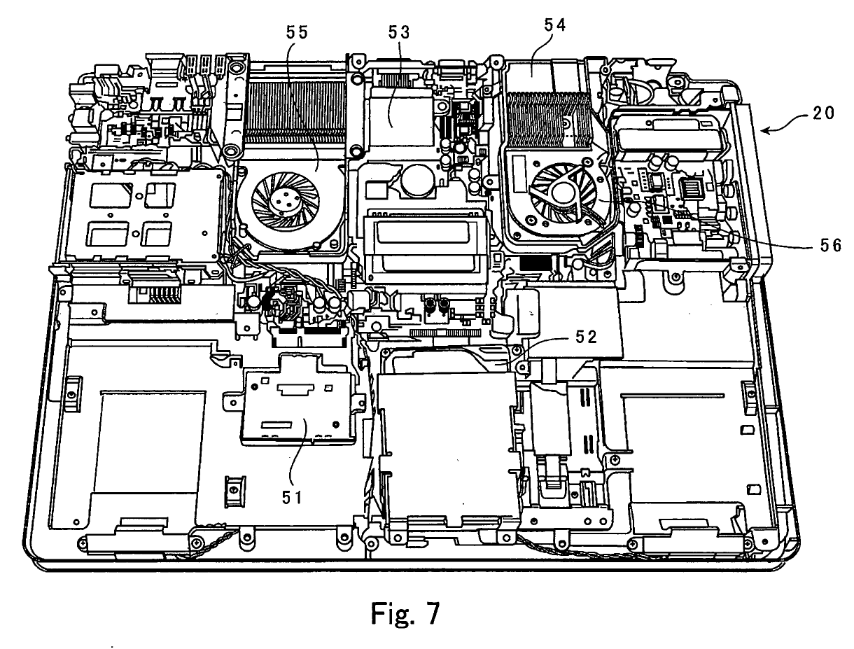

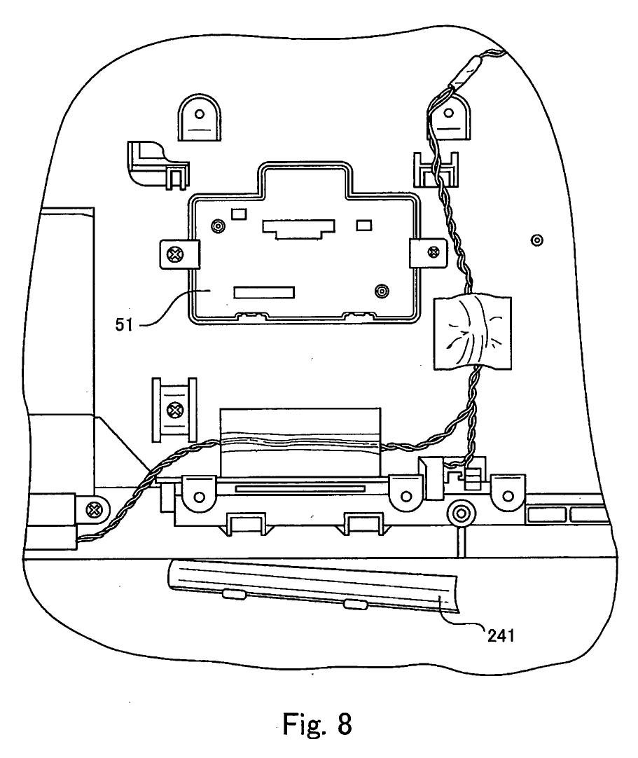

FIG. 7 is a diagram showing the inside of the main unit by placing the undersurface of the main unit pointing upward and by removing the lower cover, and FIG. 8 is an enlarged diagram of a part of FIG. 7.

When the IC card 41 is inserted into the card slot (See FIG. 6), its internal information is accessed by a card drive 51 shown in FIG. 7 and the encryption of digital TV broadcasting is decoded, and thus TV video and audio can be enjoyed with this notebook PC 10.

A hard disk unit 52 is mounted next to the card drive 51. Since the IC card 41 and the hard disk unit 52 are heat-sensitive, they are placed within the area of the front half in the main unit 20, away from heat-producing parts. On the other hand, in the back half of the main unit 20, a CPU 53, an LSI 54 for image processing, and other heat-producing parts are concentrated and thus, heat generation and cooling off are performed by means such as fans 55 and 56 that form airflow.

Here, as described above, by placing the heat-producing parts in the back half of the main unit 20 for the purpose of being cooled down, forming such a structure that the front side can be least affected by the heat, and placing the IC card 41 in the front portion thereof, the insertion and extraction of the IC card 41 can be easily performed as well as the effect of heat produced by the heat-producing parts in the main unit 20 can be suppressed to a minimum.

Although FIG. 7 shows an example in which the hard disk unit 52 is mounted next to the card drive 51, another hard disk unit for the purpose of increasing memory capacity may be additionally mounted under the card drive 51, that is, to be overlaid with the card drive 51.

Incidentally, although the description has been made about the example in which the present invention has been applied to the notebook PC, the present invention can also be applied to a computer other than the notebook PC and furthermore, to electronic devices in general.

1. An electronic device comprising:
an enclosure in the shape of a small board;
a heat-producing part incorporated within the enclosure so as to make the amount of heat produced in the back half of the enclosure become larger than the amount of heat produced in the front half; and
a card slot which is formed in the front end face of the enclosure and into which a removable IC card is inserted.

2. The electronic device according to claim 1, further comprising a card drive disposed in a position closer to the front of the enclosure to access the IC card inserted into the card slot; a hard disk unit disposed next to the card drive; and a CPU as a heat-producing part disposed deeper than the card drive and the hard disk unit.

3. (canceled)

4. The electronic device according to claim 1, wherein the enclosure has a keyboard disposed in a rearward position on an upper surface of the enclosure, and the electronic device further comprises a second enclosure in the shape of a small board on which a display screen is disposed, the second enclosure being openable and closable with respect to the former enclosure.
